(19) United States
(12) Patent Application Publication
(10) Pub. No.: US 2018/0351402 A1
(43) Pub. Date: Dec. 6, 2018

(54) CAPACITIVE POWER TRANSFER ARRANGEMENT

(71) Applicant: PHILIPS LIGHTING HOLDING B.V., EINDHOVEN (NL)

(72) Inventors: Liang SHI, EINDHOVEN (NL); Gang WANG, EINDHOVEN (NL); Feng HE, EINDHOVEN (NL)

(73) Assignee: PHILIPS LIGHTING HOLDING B.V., Endhoven (NL)

(21) Appl. No.: 15/780,158

(22) PCT Filed: Nov. 25, 2016
(86) PCT No.: PCT/EP2016/078882

§ 371 Date: May 30, 2018

(30) Foreign Application Priority Data
Dec. 1, 2015 (CN) PCT/CN2015/096112
Apr. 12, 2016 (EP) 16164781.3

(51) Int. Cl. H02J 50/05; H02J 7/02; F21K 9/232; F21K 9/238; F21V 23/00; F21V 29/70; H05B 33/08; H02M 3/335; H05K 7/20; F21V 29/508

(52) U.S. Cl. CPC H02J 50/05; H02J 7/025; F21K 9/232; F21K 9/238; F21V 23/007; F21Y 2115/10; H05B 33/0815; H02M 3/33507; H05K 7/209; F21V 29/508; F21V 29/70

(57) ABSTRACT

The invention describes a capacitive power transfer arrangement (1) for transferring power between a first electrical device (10) and a physically independent second electrical device (20), which power transfer arrangement (1) comprises a number of coupled capacitors (C1, C2), and wherein a coupled capacitor (C1, C2) comprises a first electrode (C1₁₀, C2₁₀), which first electrode (C1₁₀, C2₁₀) comprises a heatsink (H1, H2) thermally coupled to a heat dissipating component (Q, 14) of a power supply (12) of the first electrical device (10); a second electrode (C1₂₀, C2₂₀) realized in the second electrical device (20); and a dielectric layer (D) formed by a housing (16, 26) of at least one of the electrical devices (10, 20). The invention further describes a method of performing capacitive power transfer from a first electrical device (10) to a physically independent second electrical device (20); a driver (11) of an electrical device (10); and n electrical device (10) comprising such a driver (11).

### FIELD OF THE INVENTION

The invention describes a capacitive power transfer arrangement for transferring power between a first electrical device and a physically independent second electrical device. The invention also describes a method of performing capacitive power transfer; an electrical device driver; and an electrical device.

### BACKGROUND OF THE INVENTION

There is a wide range of consumer devices available today that operate using wireless technology. Many wireless devices such as sensors and controllers only require low power levels to operate. Such applications could find use in many environments such as household, commercial and industrial. The power supply of a wireless device can be a battery. When the wireless device uses a re-chargeable battery as power supply, the device must be connected to a power source in order to re-charge. However, the need to replace depleted batteries or to connect a rechargeable battery to a power supply can reduce consumer acceptance of such wireless applications.

Wireless power transfer is also a possibility for some kinds of wireless devices, removing the need to replace batteries, or to recharge. However, most known kinds of wireless power transfer solutions generally require a dedicated IC and circuitry. For example, a wireless mobile phone charger is known, and is specifically designed for charging a mobile phone using capacitive power transfer between the charger and the mobile phone. The charger is a dedicated device for this function. It must be plugged into the mains, and includes circuitry to convert the mains power into a form suitable for transfer across a capacitive power transfer interface.

A wireless application such as a sensor, controller, etc. can also be realized to draw it power from another device using wireless power transfer. The additional components necessary for the power transfer interface must be incorporated into the design of the power-donating device. The design costs and resulting product costs may be unfavourably high, and the size of the power-donating device may also become unfavourably large as a result of having to include the additional components. Therefore, consumer acceptance of such solutions may be quite low.

Therefore, it is an object of the invention to provide a simpler and more cost-effective way of supplying a wireless device with power, overcoming the problems outlined above.

US20130270922A1 and US20130270922A1 discloses using the electrical electrode in capacitive power transmission system for dissipating heat.

### SUMMARY OF THE INVENTION

It is advantageous to have a low cost wireless powering arrangement.

The basic idea of the embodiments of the invention is re-using the heat sink of an electronic device as the capacitor electrode in the capacitive powering arrangement. In the context of a driver/power supply, the heat sink attached to the power dissipating component can be used.

The object of the invention is achieved by the capacitive power transfer arrangement of claim 1; by the method of claim 8 of performing capacitive power transfer; and by the electrical device driver of claim 9.

According a first aspect of the invention, the capacitive power transfer arrangement for transferring power between a first electrical device and a physically and functionally independent second electrical device comprises a number of coupled capacitors, wherein a coupled capacitor comprises a first electrode, which first electrode comprises a heatsink thermally coupled to a heat dissipating component of a power supply of the first electrical device; a second electrode realized in the second electrical device; and a dielectric layer formed by a housing of at least one of the electrical devices.

In the context of the above aspect, the first electrical device may be regarded as the ‘transmitter’ of the capacitive power transfer arrangement, and the physically/functionally independent second electrical device may be regarded as the ‘receiver’. In such a realisation, electrical energy can be transferred from the transmitter to the independent receiver. An advantage of the inventive capacitive power transfer arrangement is that it can be realised to utilize already available components. Therefore, the capacitive power transfer can be achieved without having to specifically include the necessary parts such as a relatively large capacitor electrode as well as electrical connectors. Instead, the existing circuit design of the first electrical device can remain essentially unchanged. Adapting the first electrical device to be part of the inventive capacitive power transfer arrangement may for example only involve a more favourable arrangement of an already existing heatsink so that it can also double as a first electrode of the power transfer arrangement. The electrodes of a wireless capacitive power transfer arrangement may also be referred to as ‘plates’ since these are usually essentially flat elements that have a relatively large surface area in order to achieve a favourably high capacitance. The invention makes use of this feature in a simple and cheap solution, recognising that a heatsink is generally of metal and therefore a good electrical conductor, and generally has a relatively large surface area. The inventors have recognised that a heatsink can equally well serve as a plate of a capacitive power transfer arrangement. The capacitive power transfer arrangement according to the invention advantageously allows an existing first electrical device to also double as a power supply for a second electrical device. The second electrical device also referred to as “add-on module” in the following does not need a separate dedicated capacitive power supply, and can therefore be manufactured at lower cost.

In a preferred embodiment, the heatsink is a part of a discrete or off-the-shelf heat dissipating component. the term discrete means the component is a whole component commercially available, or is an off-the-shelf component. More specifically, it means the heatsink is an existing part of the component. Examples of this discrete component is the commercially available power switch which has a metal heat sink plate attached to the ceramic package of the semiconductors.

According to another aspect of the invention, the method of performing capacitive power transfer from a first electrical device to a physically independent second electrical device comprises the steps of providing a driver for the first electrical device, which driver comprises a power supply with a heat dissipating component, and a heatsink thermally coupled to the heat dissipating component; adapting the heatsink to serve as a first electrode of a coupled capacitor; arranging a second electrode of the coupled capacitor in the second electrical device; adapting a housing of at least one of the electrical devices to serve as a dielectric layer of the coupled capacitor; and placing the second electrical device on the first electrical device to form a coupled capacitor comprising the first and second electrodes on either side of the dielectric layer.

The method according to the invention allows a simple and cheap realisation of an add-on module (i.e. the second electrical device) that can draw its power from an already existing device. It is not necessary to provide a dedicated power supply module for the add-on module. The inventive method therefore allows an existing installation for example any electrical device that has a heat-dissipating component and corresponding heatsink—to be used as a power supply for an add-on module.

According to the invention, the driver of an electrical device (LED lamp) comprises a power supply comprising a number of heat dissipating components; and a heatsink thermally coupled to a heat dissipating component, wherein the heatsink is adapted to function as a first electrode of a coupled capacitor of a capacitive (wireless) power transfer arrangement between that electrical device and a physically independent second electrical device.

The inventive driver can be designed and manufactured with minimal additional effort to also act as a power supply for any appropriate wireless add-on module. The driver design need only consider a favourable placement of a heatsink, and possibly also an electrical connection to the heatsink, allowing it to act as a transmitter plate when a device incorporating that driver is later used as a power supply for an add-on module.

According to the invention, the electrical device comprises an electrical load; the inventive driver as described above to supply power to the electrical load; and a device housing realised as a dielectric layer of at least one coupled capacitor of the capacitive power transfer arrangement between that electrical device and the physically independent second electrical device.

An advantage of the inventive electrical device is that it can fulfil its actual intended function while also serving as a power supply for an add-on module. The added functionality is obtained with favourably low effort, since such an electrical device requires a driver and a device housing in any case. These components continue to fulfil their intended function and can simultaneously be used to also act as part of a capacitive power transfer arrangement.

The dependent claims and the following description disclose particularly advantageous embodiments and features of the invention. Features of the embodiments may be combined as appropriate. Features described in the context of one claim category can apply equally to another claim category.

In the following, the expressions “first electrical device” and “transmitter” may be used interchangeably. The same applies to the expressions “second electrical device” and “receiver”. The terms “conductor”, “electrode” and “plate” may also be used interchangeably. The capacitive wireless power transfer arrangement according to the invention can be used to transfer power between any two physically independent electrical devices. It is only necessary for the conductor plates of the two devices to face each other across the dielectric layer.

Intelligent lighting is becoming more widespread in household and commercial environments. Lighting units such as retrofit LED lamps can be connected over a wireless network, for example a ZigBee network, a wireless local area network, etc. It has been proposed to extend the functionality of such a lighting network by incorporating add-on modules such as sensors or controllers. In the following, but without restricting the invention in any way, it may be assumed that the first device is a relatively small device such as an LED lamp. An LED lamp such as a retrofit lamp is generally constructed in such a way that the lamp driver and the LED light source (one or more LEDs) are enclosed in a single unit. The unit can comprise a translucent cover enclosing the LED light source, and a (usually opaque) housing that encloses any electrical components such as the driver, power converter etc. The housing and its enclosed circuitry is generally arranged between the translucent cover and the electrical contacts, for example an E27 connector, a G13 connector etc. The terms “first electrical device” and “LED lamp” may be used interchangeably in the following, but it shall be noted that the first electrical device can be any appropriate device, i.e. a device with a heat-dissipating component and a corresponding heat sink.

The add-on module can be shaped to fit onto the housing of the first electrical device. Although not strictly necessary, it may be assumed that the add-on module is considerably smaller than the first electrical device. In a preferred embodiment of the invention, the add-on module comprises a sensor module such as an occupancy sensor, a light level sensor, an acoustic sensor, etc. When mounted onto the housing of an LED lamp of a ceiling or wall lighting fixture, such a sensor can be favourably placed to detect movement, sound, light levels, etc. Such a second electrical device is therefore not only physically separate or independent of the first electrical device it is also functionally separate or independent. Of course, the add-on module may be a function extension module such as an energy monitoring module, a wireless communication module etc., that extends the function of the first electrical device. For example, an energy monitoring module can keep track of the power consumption of the first electrical device. A combination is also possible, for example, the add-on module can comprise a light level sensor to carry out a task independent of the first electrical device, and a wireless communication module to extend the function of the first electrical device. When the first electrical device is an LED lamp, the wireless communication module can communicate with the lamp's driver and/or a central wireless commination device such as a ZigBee bridge, WLAN router etc. to switch on/off the lamp according to the ambient light levels.

In a particularly preferred embodiment of the invention, the electrical load of the LED lamp comprises a number of LEDs, and the driver comprises a switched-mode power supply enclosed in the housing. Switched-mode power supplies are attractive owing to their compact size and favourably low power consumption. A switched-mode power supply operates by continually switching a pass transistor between full-on and full-off states. The pass transistor—a field-effect transistor (MOSFET), a bipolar junction transistor (BJT), etc.—is generally referred to as the ‘power switch’. Even though the transistor spends only very little time in the high-dissipation transition states, the rapid switching at frequencies of about 16 kHz cause the transistor to become very hot. To avoid damage, such a transistor is generally thermally coupled to a heat sink, for example by direct physical contact, or means of an intermediate heat spreader. In a particularly preferred embodiment of the invention, the first conductor of a coupled capacitor comprises the heatsink of the power switch of the power supply of the first electrical device. The heatsink can be electrically and thermally coupled to the hottest pin of the power switch, for example to the drain terminal of a MOSFET or the gate terminal of a BJT, and is preferably positioned and dimensioned to act as the first conductor of a capacitor of a wireless power transfer arrangement. Preferably, the heatsink is arranged so that it can lie against the dielectric layer formed by the housing that encloses the power supply. When the power switch is turned “off”, the voltage on the heatsink will rise to a maximum level. When the power switch is turned “on”, current flows through the switch and the voltage on the heatsink will drop to a minimum level. In this way, an oscillating voltage is applied to the transmitter plate connected to the power switch whenever the first electrical device is being operated. The power transfer arrangement according to the invention essentially re-uses the high voltage switching of the first electrical device's power converter to also charge and discharge the coupled capacitors. The add-on module may incorporate suitable circuitry, known from the prior art, to establish a one-way path for the transferred energy to the load of the add-on module.

In a preferred embodiment of the invention, the wireless power transfer arrangement is a bipolar arrangement, comprising a first coupled capacitor and a second coupled capacitor. The first electrical device comprises two transmitter plates, and the second electrical device comprises two receiver plates. Preferably, the plates of the receiver are connected across a rectifier converter stage of the second electrical device to prevent energy transfer back to the transmitter. Using the example described above, a first transmitter plate can be electrically connected to a pin of the power switch. To complete the circuit, a second transmitter plate can be electrically connected to ground. An oscillating potential between the two transmitter plates induces an opposite oscillating potential between the two receiver plates.

The power switch is not the only heat-dissipating component of a switched-mode power supply. A power converting component such as a transformer or rectifier of the power supply can also dissipate a significant quantity of heat. For this reason, a heatsink is generally also provided to draw heat away from such a power converting component. In a preferred embodiment of the invention, therefore, a transmitter plate of a coupled capacitor comprises a heatsink thermally coupled to a power converting component of the first electrical device. In this case also, the heatsink is preferably arranged so that it can lie against the dielectric layer formed by the housing that encloses the power supply. In a particularly preferred embodiment of the invention, the first electrical device comprises a first heatsink adapted to function as the first conductor of a first coupled capacitor of a bipolar power transfer arrangement, and a second heatsink adapted to function as the first conductor of a second coupled capacitor of the power transfer arrangement. The first conductors of the coupled capacitors can be realised in the transmitter or first electrical device as described above. The second conductors of the coupled capacitors are then realised in the receiver or second electrical device. A rectifier arranged across the second conductors in the second electrical device ensures that power is only transferred from the transmitter device to the receiver device.

In a preferred embodiment of the invention, as described above, the transmitter of the capacitive power transfer arrangement is an LED lamp with a housing that encloses its driver and power supply. For a retro-fit LED lamp for a fixture with a connector such as an E27 or E14 socket, the housing is preferably cup-shaped to resemble the shape of an incandescent lamp. In some known designs, the housing can have a cup-shaped non-conductive exterior layer and a metal inner layer shaped to complement the cup-shaped exterior layer. The metal inner layer serves as a heatsink for the LED chips, or the heat-dissipating component such as a power switch of a transformer of the power supply, and a similarly-shaped plastic outer layer that acts as an electrical insulator. The metal inner layer may be made of a light material such as aluminium, which is also a good thermal conductor. In an LED lamp according to the invention, at least one transmitter plate is a part of the cup-shaped metal inner layer. In a bipolar power transfer arrangement, one region of the cup-shaped metal inner layercan be reserved for the first transmitter plate, and another region of the cup-shaped metal inner layercan be reserved for the second transmitter plate. Such a region may also be referred to as a ‘body electrode’ in the following, being an electrode or transmitter plate arranged in the body of the device housing. For example, one relatively small region on the metal inner layer can make electrical contact with a high frequency voltage switching node. The remaining inside surface of the housing can make electrical contact to the ground terminal of the driver, thus acting as the second transmitter plate. The first region, being relatively small, is preferably realised using a good conductor such as steel or copper. The second region, being relatively large, can be made of a lighter and cheaper conductor such as aluminium. Reliable electrical contact to a body electrode can be improved by an electrically conductive element such as a jumper. Such an electrically conductive element may also be spring-loaded in order to further improve the electrical contact.

As indicated above, a heat sink can be in direct thermal contact to the heat-dissipating component. The power switch of regular switching converter is one of the parts that generate a lot of heat. For a driver with a power rating exceeding 30 W, a power switch incorporating a heatsink is necessary to dissipate heat in order to ensure that the switch temperature remains within an acceptable range. Such a power switch can be supplied as a unit already comprising a metal heatsink, with the ‘hot’ pin of the power switch electrically and thermally coupled to the metal heatsink. Devices are available in which the heat sink is realised as an aluminium block that is already screwed or clamped to the power switch. Alternatively, a heatsink may be available as a separate component which can be can be clamped or screwed to the transistor package.

Alternatively, a heatsink can be thermally coupled to a heat dissipating component via a heat spreader. In the case of the second coupling capacitor, the heat-dissipating component is located in the power converter. Here, the heat can be transferred to the heatsink over an intervening heat spreader such as a metal layer in the printed circuit board (PCB) of the LED light sources.

To be able to function effectively, the wireless power transfer arrangement requires that the conductors of a coupled capacitor face each other across the dielectric. The capacitance of the coupled capacitor can be maximised by correctly arranging the transmitter plate(s) relative to the receiver plate(s). However, the conductors of the transmitter and receiver devices may be concealed inside the respective device housings, so that a user cannot readily identify the locations of the conductors, and may be uncertain whether the placement of the add-on module is correct. Therefore, in a particularly preferred embodiment of the invention, a device housing can comprise a physical indicator of the location of a conductor of a coupled capacitor. For example, the device housing of the first electrical device may have a visible outline that corresponds to the outline of the second electrical device. The user can then easily identify the region onto which the second electrical device should be placed. In a preferred embodiment of the invention, a device housing can comprise a relief structure that corresponds to the location of a conductor or plate. For example, the first and second electrical devices can comprise complementary ridged or grooved patterns that define the optimal placement. An advantage of such a design is that it becomes very easy for a user to align the receiver plates (concealed in the add-on module) face to face with the transmitter plates (concealed in the first electrical device).

In a particularly preferred embodiment of the invention, a heatsink acting as a coupled capacitor plate also comprises a relief structure to complement the relief structure of the device housing. Such an embodiment has the advantage of increasing the surface area of the heatsink, thereby also increasing its efficiency. Another advantage of using relief structures for the capacitor plates is that assembly of the electrical devices may be simplified.

Other objects and features of the present invention will become apparent from the following detailed descriptions considered in conjunction with the accompanying drawings. It is to be understood, however, that the drawings are designed solely for the purposes of illustration and not as a definition of the limits of the invention.

### BRIEF DESCRIPTION OF THE DRAWINGS

FIG. 1 shows a schematic circuit diagram of an embodiment of a capacitive power transfer arrangement according to the invention;

FIG. 2 shows a simplified model for the circuit of FIG. 1;

FIG. 3 shows a block diagram of an embodiment of a capacitive power transfer arrangement according to the invention;

FIG. 4 shows a power switch of a power supply of a driver according to the invention;

FIG. 5 is a schematic diagram of an embodiment of a capacitive power transfer arrangement according to the invention;

FIG. 6 shows an interior view of the first electrical device of FIG. 5;

FIG. 7 is a schematic diagram of an embodiment of a second electrical device for the capacitive power transfer arrangement according to the invention;

FIG. 8 shows an interior view of the second electrical device of FIG. 7;

FIG. 9 shows one embodiment of a capacitive power transfer arrangement according to the invention;

FIG. 10 shows a further embodiment of a capacitive power transfer arrangement according to the invention;

FIG. 11 shows graphs of voltage and current during operation of the capacitive power transfer arrangement according to the invention;

FIG. 12 shows a prior art capacitive power transfer arrangement.

In the drawings, like numbers refer to like objects throughout. Objects in the diagrams are not necessarily drawn to scale.

### DETAILED DESCRIPTION OF THE EMBODIMENTS

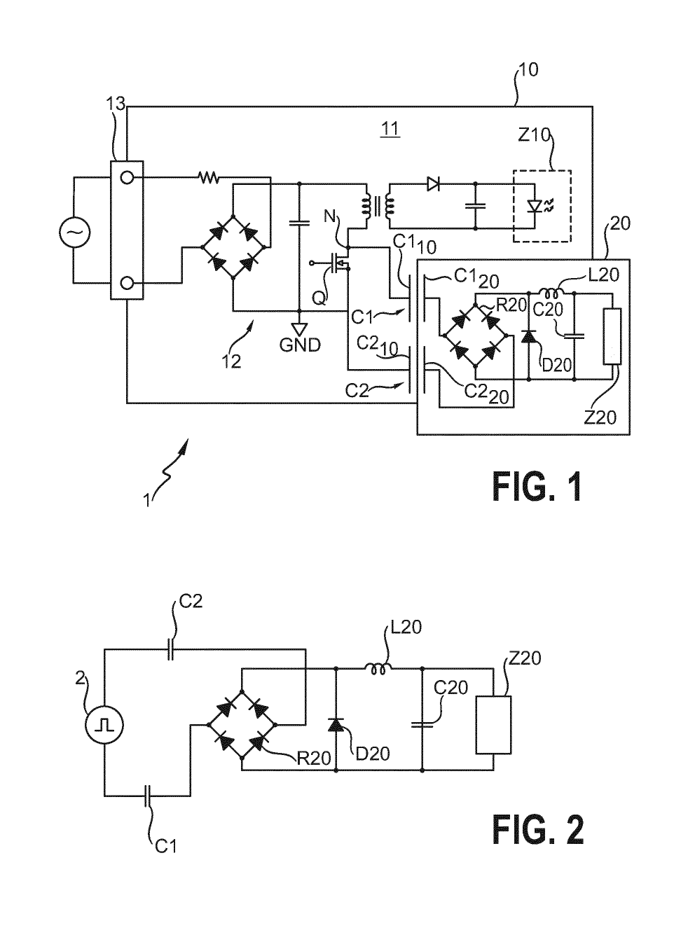

FIG. 1 shows a schematic circuit diagram of an embodiment of a capacitive power transfer arrangement 1 according to the invention, in a bipolar realisation with two coupled capacitors C1, C2 for transferring power from a first electrical device 10 to a second electrical device 20.

The first electrical device 10 is shown to have a driver 11 for driving a load Z10, in this case an LED light source L₁₀. The driver 11 incorporates a diode bridge rectifier and a switched-mode power supply 12, in this case a flyback converter 12, to convert mains input to a DC output for the load Z10. The switched-mode power supply 12 uses a transistor switch Q, in this case a MOSFET 10, to perform rapid on/off switching of the DC output voltage in the usual manner when a pulse-width modulation control signal is applied to the control input of the transistor switch. In this exemplary embodiment, a first plate/electrode C1₁₀ of the first coupled capacitor C1 is electrically connected to node N at the drain terminal of the MOSFET Q, and a first plate/electrode C2₁₀ of the second coupled capacitor C2 is electrically connected to ground GND.

The second electrical device 20 comprises a load Z20 and a power supply circuit for receiving power via the coupled capacitors C1, C2. To this end, the second electrical device 20 comprises a second plate/electrode C1₂₀ of the first coupled capacitor C1 and a second plate/electrode C2₂₀ of the second coupled capacitor C2, arranged about a diode bridge rectifier R20

FIG. 2 shows a simplified model to demonstrate the charging loop for the power transfer arrangement of FIG. 1. A buffer capacitor C20 is chosen to be much larger than either of the coupled capacitors C1, C2, and can therefore be neglected in the high-frequency oscillation analysis. Each switching event of the transistor Q of the first electrical device 10 can be regarded as a pulse, as indicated by the symbol 2 replacing the driver circuitry, and an alternating or oscillating input results across the rectifier R20 when the switched-mode power supply 11 is operational. The inductor L20 takes part in the oscillation, drawing the same energy as the energy stored in a coupled capacitor C1, C2 during each pulse. The inductor current may be assumed to be zero at the beginning of each cycle. The diode D20 completes a freewheel path for the inductor current. The diode bridge R20 prevents the inductor current from returning to the source (the coupled capacitors C1, C2) so that the total energy inside inductor L20 can charge the buffer capacitor C20.

The ideal total energy transferred from the first electrical device 10 to the second electrical device 20 can be calculated as follows:

P=½CV_{DS}²2f (1)

where C is the capacitance of the series coupled capacitors C1, C2; f is the switching frequency of the converter 12, and V_{DS} is the switching voltage of the converter. In the example given above, the switching voltage is the drain-to-source voltage of the MOSFET Q. This switching voltage can be equal to the bus voltage, depending on the driver topology. Since each switching period includes two switching events (turn on, turn off), the circuit charging frequency is twice the switching frequency f of the power switch Q. The capacitance C is determined by the electrode or plate dimensions of the coupled capacitors C1, C2, the distance between opposing plates, and the dielectric material between them:

$$C = ɛ \cdot {ɛ}_{0} \cdot \frac{S}{d} \qquad ( 2 )$$

Where ε is the relative dielectric constant of the dielectric material, ε₀ is the permittivity of a vacuum, i.e. 8.86×10⁻¹², S is the electrode area, and d is the distance between opposing electrodes. For example, two 3.0 cm square electrodes with 1.0 mm distance can result in a capacitance C of about 80 pF when the material between the electrodes has a dielectric constant of about 10. For example, a ceramic material can have a dialectic constant of about 10.

If the transistor switching frequency f is about 16 kHz, and the amplitude of the switching voltage V_{DS} is about 400 V, the maximum power that can ideally be transferred to the second electrical device 20 can be calculated to be about 0.6 W. In an actual realisation, the add-on module 20 may only be able to extract about 0.5 W on account of a non-zero inductor current at the beginning of each pulse, the V/s switching rate and power loss in the charging loop. Simulations carried out in the course of the invention have shown that the add-on module 20 can extract more power from the first electrical device 10 when a relatively large inductor L20 is used, for example an inductor L20 with a value of 1.0 mH. A larger inductor is associated with a smaller charging current spike and a lower power loss in the first device.

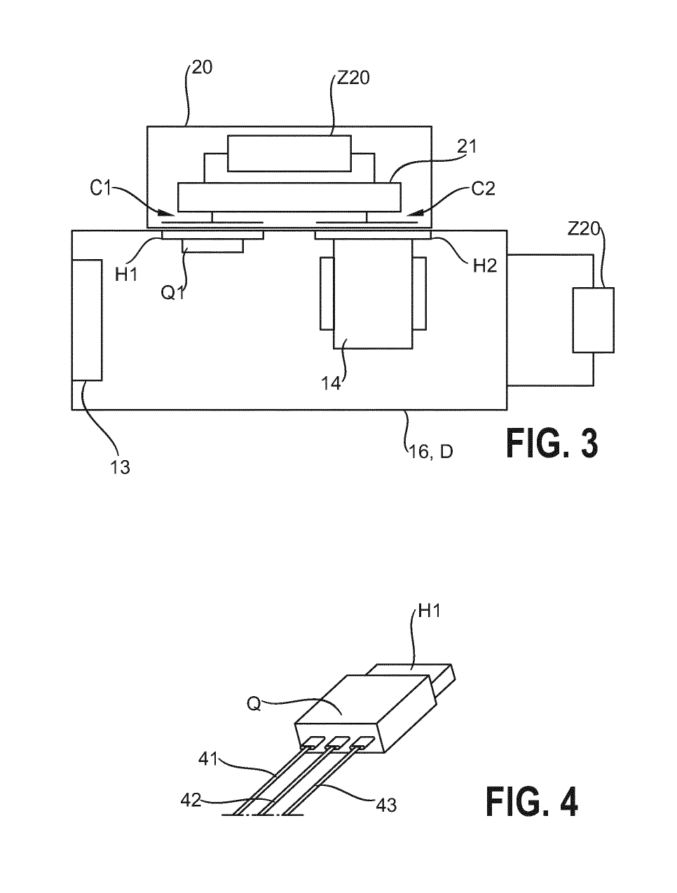

FIG. 3 shows a simplified block diagram of a capacitive power transfer arrangement 1, showing how two heatsinks H1, H2 of a first electrical device 10 can also serve as transmitter plates C1₁₀, C2₁₀ of the coupled capacitors C1, C2 of the power transfer arrangement 1. For simplicity, only the relevant components of the first electrical device 10 are shown, i.e. a connector interface 13 for connecting to a mains power supply, a load Z10, a transformer 14 and a power switch Q of a converter (not shown). A simplified add-on module 20 is also shown, with converter circuitry 21 as descried above, and a load Z20. The heatsink H1 of the first electrical device 10 may be in direct thermal contact with the power switch Q, and also in electrical contact with the pin corresponding to node N in FIG. 1. When the power switch Q is a MOSFET, this would be the drain pin. In the case of a BJT transistor switch, the node N may correspond to the component's collector pin. The invention makes use of the fact that the metal plate carries the high switching voltage during operation of the driver, and that it is possible to also use the metal plate in the electrode of a coupled capacitor for wireless charging. Alternatively, the heatsink H2 can be the heatsink of the rectifier bridge R20.

FIG. 4 shows an off-the-shelf MOSFET device, with three pins 41, 42, 43 for source, drain and gate terminals respectively. The diagram also shows a heatsink H1 in direct thermal contact with the body of the component. To also function as a transmitter plate of a coupled capacitor in this exemplary embodiment, the heatsink H1 must be connected to the drain terminal 42 of the power switch Q. The housing 16 of the first electrical device 10 also serves as the dielectric D of the two coupled capacitors C1, C2.

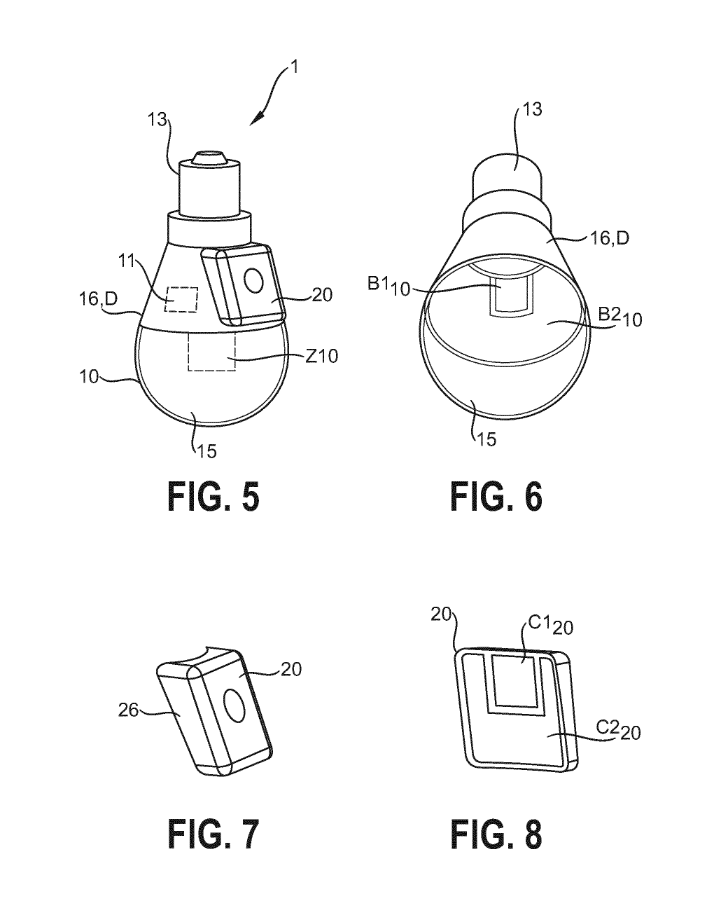

The above embodiments show that how the heatsink of the power switch, the transformer or the rectifier can be re-used as the capacitor electrode of capacitive power transfer. The below embodiment will show the heatsink of a lamp/bulb is re-used as the capacitor electrode of capacitive power transfer. FIG. 5 is a schematic diagram of an embodiment of a capacitive power transfer arrangement 1 for which the first electrical device 10 is a retrofit LED lamp 10. The lamp 10 has a socket 13 for connecting to a lighting fixture and mains power supply (not shown). The LED light source of the lamp 10 is enclosed in a translucent cover 15, while the driver is concealed inside a cup-shaped opaque housing 16. The arrangement of load Z10 and driver 11 is indicated by the broken lines. The overall shape of the LED lamp 10 corresponds to the shape of a legacy incandescent bulb. The capacitive power transfer arrangement 1 uses the driver of the LED lamp 10 to supply power to an add-on module 20, which is shown in place on the outer surface of the housing 16. The housing 16 comprises an exterior layer and an interior layer. It is common to form the housing of LED lamp in structure of a metal over moulded with plastic wherein the metal is used as the heatsink of the lamp and thermally coupled to the LED chips and/or the heat dissipating element in the driver 11. The present embodiment proposes that the exterior layer serves as a dielectric D of the coupled capacitors of the power transfer arrangement 1, and the interior layer is a heatsink of the lamp while is also conductive and re-used as the electrode of coupled capacitors. The add-on module can be some kind of sensor and/or a control device to extend the functionality of the LED lamp 10 or the functionality of a lighting network of which the LED lamp is a part.

FIG. 6 shows a simplified view into the interior of the LED lamp 10 of FIG. 5. For the sake of clarity, no parts are shown other than the interior of the housing 16, D. On the inside surface of the housing 16, it is interior layer and the two body electrode regions B1₁₀, B2₁₀ are shown. Thermal contact can also be made between the larger region B2₁₀ and the LED load, for example via a metal heat spreader of a PCB to which the LEDs are mounted. Wither reference to FIGS. 1 and 3, the smaller region B1₁₀ will be the transmitter plate C1₁₀ of a first coupled capacitor C1, while the larger region B2₁₀ will be the transmitter plate C2₁₀ of a second coupled capacitor C2. Preferably, the smaller body electrode region B1₁₀ is electrically connected to the high-voltage switching node (e.g. node N in FIG. 1) to ensure satisfactory electromagnetic compatibility (EMC). As mentioned above, the exterior layer of the housing 16 will serve as the dielectric D of the coupled capacitors. The smaller body electrode region B1₁₀ can be connected to a high frequency voltage switching node, while the ground terminal of the driver can make electrical contact to the larger body electrode region B2₁₀. Since the driver is inside the housing of the lamp, it is physically close to the metal of the body electrodes B2₁₀, and it is relatively easy to electrically connect the ground terminal of the driver (e.g. node GND in FIG. 1 when the driver is realised using a flyback topology) to the larger region B2₁₀, for example by a jumper or a spring-loaded part. Since there is a relatively high voltage difference between the transmitter plates of the coupled capacitors, the insulating region between these two body electrode regions B1₁₀, B2₁₀ should be of a suitable material, for example plastic, and should be sufficiently wide.

FIG. 7 is a schematic diagram of an embodiment of an add-on module 20 for the capacitive power transfer arrangement 1 according to the invention. This diagram shows how the housing 26 of the add-on module 20 can be shaped to complement the cup-shaped housing of the LED retro-fit lamp 10 of FIGS. 5 and 6. FIG. 8 shows the underside of the add-on module 20 of FIG. 7, i.e. the face that will lie against the LED lamp housing 16. This diagram clearly shows the two receiver plates C1₂₀, C2₂₀ or exposed metal pads C1₂₀, C2₂₀ of the coupled capacitors. The smaller receiver plate C1₂₀ is shaped to correspond to the smaller region C1₁₀ in the lamp housing interior, while the larger receiver plate C2₂₀ will cover only part of the larger region C2₁₀ in the lamp housing interior. When the add-on module 20 is attached to the LED lamp 10 of FIG. 5, the transmitter and receiver plates face each other across a very small distance (the thickness of the housing). The add-on module can be physically secured to the first electrical device 10 in any suitable manner, for example by an adhesive connection.

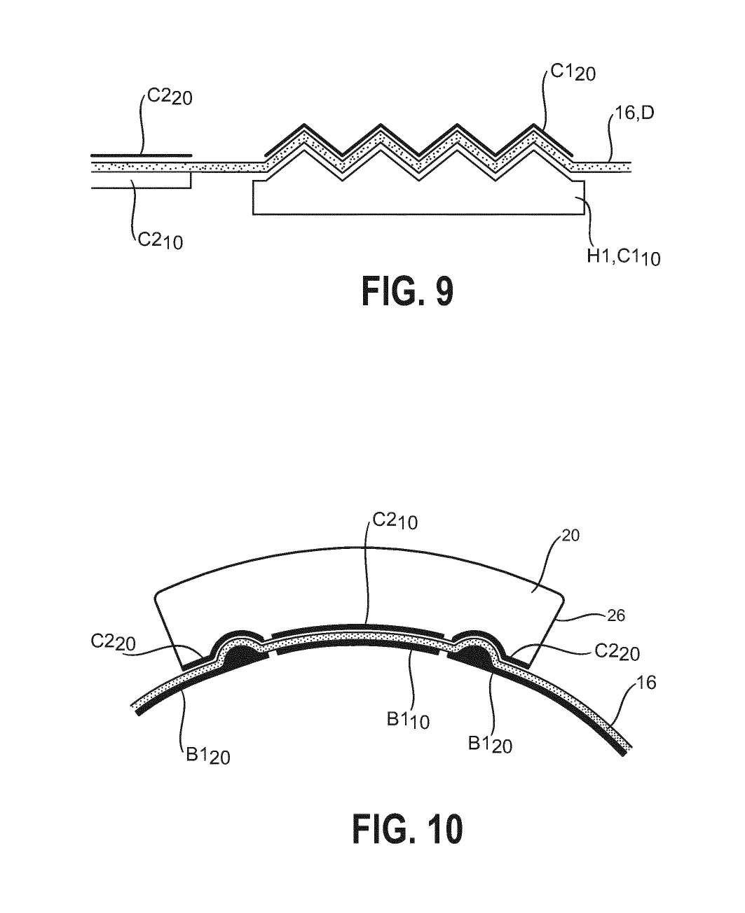

For a user to be able to correctly place an add-on module 20 onto a first electrical device 10 in order to complete the capacitive power transfer arrangement 1, the position of an electrode of a coupled capacitor can be indicated visually, for example by a distinct surface pattern. FIGS. 9 and 10 show cross-sections through possible embodiments of a capacitive power transfer arrangement according to the invention. In FIG. 9, ridges or grooves have been formed in the housing 16 of the first electrical device 10 in a region corresponding to the position of a transmitter plate C1₁₀ in the interior of the first electrical device 10. The transmitter plate C1₁₀ itself is also shaped to match the ridged surface of the housing 16. When the transmitter plate C1₁₀ also acts as a heatsink H1 of a power switch, the additional surface area can improve the heat dissipating function of the heatsink H1. In the add-on module, the receiver electrode C2₁₀ is also shaped to match the ridged surface of the housing 16. In this embodiment, the area of the electrode is increased and in turn the capacitance is increased.

Using the realisation described in FIGS. 5-8, FIG. 10 shows a cross-section through a lamp housing 16 and add-on module housing 26, showing dunes formed in the driver housing 16 and add-on module housing 26, corresponding to the outline of the receiver plate C2₂₀ in the add-on module 20. Such a haptic or three-dimensional pattern, even if only restricted to the region of one coupled capacitor, can uniquely identify the ideal position for the add-on module 20 relative to the first electrical device 10, so that the total capacitance of the coupled capacitors C1, C2 and the power transferred to the add-on module 20 are maximised.

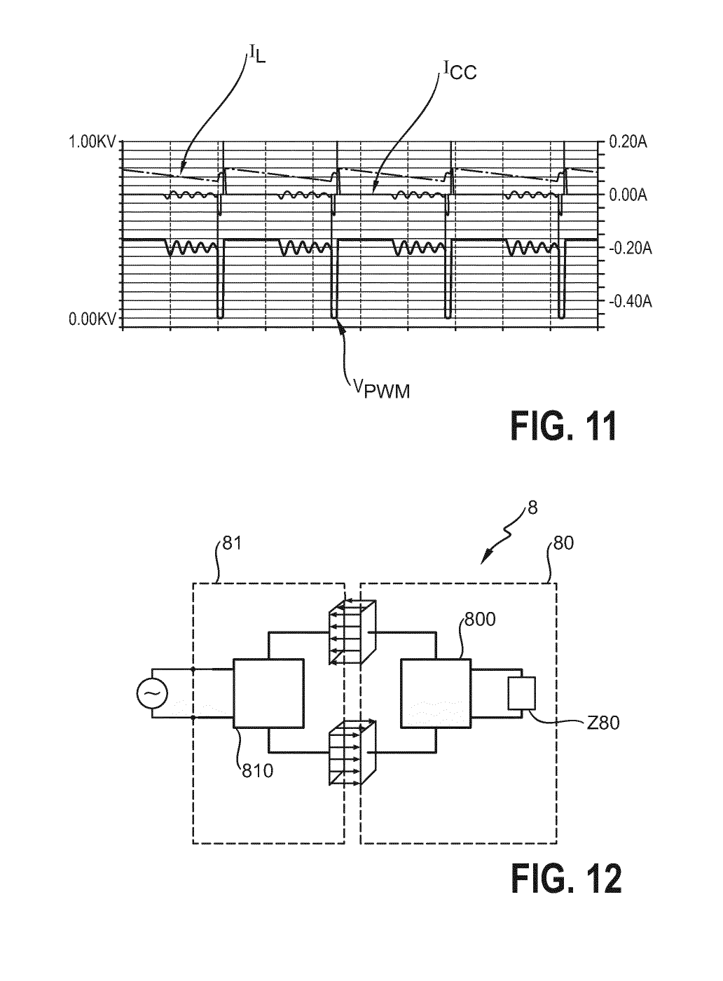

FIG. 11 shows graphs of voltage and current during operation of the capacitive power transfer arrangement 1, namely the charging current I_{CC} of the coupled capacitors, the inductor current IL, and a driver control signal V_{PWM} for controlling the power switch. When the power switch (e.g. switch Q in FIG. 1) is turned off, the high voltage across the switch charges the coupled capacitors, indicated by the spikes on the charging current waveform I_{CC}. When the power switch is turned on, the coupled capacitors discharge into the inductor L20. The inductor L20 charges and discharges accordingly, as shown by the inductor current waveform IL, which shows an increasing current when the power switch transitions between its “on” and “off” states, and a decreasing current for the duration of an “on” or “off” state. This inductor current IL, charges the buffer capacitor C20 of the add-on module, thereby supplying the load Z20 with current as long as the power switch is being turned on/off during operation of the first electrical device 10.

FIG. 12 shows a prior art capacitive power transfer arrangement, as used for example to re-charge a mobile phone or similar device 80. A dedicated charging unit 81 is required, with a converter 810 for converting a mains supply into a form suitable for charging and re-charging the coupled capacitors of the power transfer arrangement. The device 80 comprises a converter 800 for converting the oscillating charge at the interface to a charging current for a re-chargeable battery L80 of the device 80.

Although the present invention has been disclosed in the form of preferred embodiments and variations thereon, it will be understood that numerous additional modifications and variations could be made thereto without departing from the scope of the invention. For example, the “hot” pin of the power switch (e.g. the drain pin of a MOSFET) can be directly connected to the first conductor of a coupled capacitor by means of an electrically and thermally conducting jumper or other suitable bridging part. In such an embodiment, the connector (or the connector together with the first conductor) may be regarded as a heatsink of the power switch.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

1. A capacitive power transfer arrangement for transferring power between a first electrical device and a physically independent second electrical device, the power transfer arrangement comprising first and second coupled capacitors, wherein each of the coupled capacitors comprises:
a first electrode comprising a heatsink thermally coupled to a heat dissipating component of a power supply of the first electrical device;
a second electrode realized in the second electrical device; and
a dielectric layer formed by a housing of at least one of the electrical devices.

2. The power transfer arrangement according to claim 1, wherein the heatsink is a part of a discrete or off-the-shelf heat dissipating component, and
the housing comprises a relief structure in a region corresponding to the location of the first electrode of the first coupled capacitor in the first electrical device.

3. The power transfer arrangement according to claim 1, wherein the first electrode of the first and second coupled electrodes comprises a relief structure to complement the relief structure of the device housing.

4. The power transfer arrangement claim 1, wherein the heatsink of the first electrode of the first coupled electrode is comprised of a power switch of the power supply of the first electrical device.

5. The power transfer arrangement according to claim 1, wherein the heatsink of the first electrode of the second coupled electrode is comprised of a power converting component of the power supply of the first electrical device.

6. The power transfer arrangement according to claim 5, wherein said power converting component comprises a transformer or a rectifier of the power supply.

7. The power transfer arrangement according to claim 1, wherein the second electrode of the first and second coupled capacitors comprises terminals of a rectifier converter stage of the second electrical device.

8. The power transfer arrangement according to claim 1, wherein the second electrical device comprises a sensor module and a function extension module realized to extend the function of the first electrical device.

9. A driver of an electrical device, the driver comprising:
a power supply comprising a plurality of heat dissipating components; and
a heatsink thermally coupled to the heat dissipating components;
wherein the heatsink is adapted to function as a first electrode of at least one of the first and second coupled capacitors of the capacitive power transfer arrangement of claim 1, between the first electrical device and the physically independent second electrical device.

10. The driver according to claim 9, wherein the heatsink is a part of the discrete or off-the-shelf heat dissipating component, and
the power supply is configured as a switched-mode power supply including a heat dissipating component, which comprises a semiconductor power switch.

11. The driver according to claim 9, wherein the heat dissipating component comprises a power converting component of the power supply.

12. The driver according to claim 9, wherein the first heatsink is adapted to function as the first electrode of the first coupled capacitor of the power transfer arrangement, and wherein the second heatsink is adapted to function as the first electrode of the second coupled capacitor of the power transfer arrangement.

13. An electrical device comprising
an electrical load;
a driver according to claim 9 configured to supply power to the electrical load; and
a housing configured as a dielectric layer of at least one of the first and second coupled capacitors of the capacitive power transfer arrangement between that electrical device and the physically independent second electrical device.

14. The electrical device according to claim 13, further comprising an LED lamp for which
the electrical load comprises a number of LEDs;
the driver comprises a switched-mode power supply; and
the housing, is adapted to accommodate at least the switched-mode power supply.

15. An LED lamp, comprising:
an electrical load comprising a number of LEDs;
a driver;
a housing adapted to accommodate the driver, wherein said housing comprises;
a cup-shaped dielectric exterior layer;
an interior heat sink layer thermally coupled to the electrical load or the driver so as to sink the heat dissipated by said electrical load or the driver, said interior heat sink layer comprising at least a first electrically conductive portion and a separate second electrically conductive portion, wherein the electrically conductive portions are shaped according to the cup-shaped dielectric layer; and wherein
the first electrically conductive portion is an element of the first electrode of a first coupled capacitor of a capacitive power transfer arrangement; and
the second electrically conductive portion is an element of the first electrode of a second coupled capacitor of the capacitive power transfer arrangement.
